(19) United States
(12) Patent Application Publication
(10) Pub. No.: US 2025/0220853 A1
(43) Pub. Date: Jul. 3, 2025

(54) COOLANT MODULE SYSTEM AND COOLANT MODULE SYSTEM CONTROL METHOD FOR ELECTRIC VEHICLES

(71) Applicant: Hanon Systems, Daejeon (KR)

(72) Inventors: Sang Hun Kim, Daejeon (KR); Jin Hyun Jang, Daejeon (KR); Byoung Su Lee, Daejeon (KR)

(21) Appl. No.: 18/982,605

(22) Filed: Dec. 16, 2024

(30) Foreign Application Priority Data
Dec. 27, 2023 (KR) 1020230193599

(51) Int. Cl. H05K 7/20

(52) U.S. Cl. CPC H05K 7/20281; H05K 7/20272; H05K 7/20845

(57) ABSTRACT

A coolant module system and a method for controlling the coolant module system for an electric vehicle. The coolant module system includes a coolant pump configured to press and transfer a coolant; a coolant valve configured to control a flow of the coolant in a plurality of directions; and a control unit configured to control operations of the coolant pump and the coolant valve and to control an operational speed of the coolant pump to be equal to or below a preset RPM (revolutions per minute) when a mode of the coolant valve is changed.

### CROSS REFERENCE TO RELATED PATENT APPLICATION

This patent application claims the benefit of and priority to Korean Patent Application No. 10-2023-0193599 filed on Dec. 27, 2023, the entire contents of which are incorporated herein by reference for all purposes.

### TECHNICAL FIELD

The present disclosure relates to a coolant module system and a method for controlling the coolant module system for an electric vehicle, in particular, a coolant module system using a coolant module in which an electric water pump (eWP) and a coolant valve are assembled into a single module and a method for controlling the coolant module system.

### BACKGROUND ART

The electric water pump (eWP) is a device configured to control a flow rate of a coolant, and many researches and developments have been conducted on the electric water pump along with the development of the electric vehicles.

Meanwhile, the conventional electric water pump controls the flow rate in one direction only, however, recently, a coolant module having a coolant valve configured to change a direction of a flow path mounted on the electric water pump has been developed. Such a coolant module can not only control a flow rate of the coolant, but also can control a flow path direction of the coolant.

In the integrated coolant module, there may occur a case in which a transfer path of the coolant is dramatically or sharply changed according to a direction of the coolant valve. In this case, when the electric water pump is operated at a high speed, noise, and/or vibration may be generated due to instability of the flow path. This may have an adverse effect on the durability of the product, and provide passengers with unnecessary noise and/or vibration.

### SUMMARY

An object of the present disclosure is to provide a coolant module system capable of reducing noise and/or vibration when changing a flow path in a state in which a flow rate of a coolant is great, and a method for controlling the coolant module system.

The technical problem to be achieved by the present disclosure is not limited to the above-mentioned technical problem, and other technical problems that are not mentioned will be clearly understood by ordinary-skilled persons in the art to which the present disclosure pertains from the following description.

One embodiment is a coolant module system, including: a coolant pump configured to press and transfer a coolant; a coolant valve configured to control a flow of the coolant in a plurality of directions; and a control unit configured to control operations of the coolant pump and the coolant valve and to control an operational speed of the coolant pump to be equal to or below a preset RPM (revolutions per minute) when a mode of the coolant valve is changed.

The coolant module system may include: a plurality of cooling flow paths connected to the coolant valve, and when a mode of the coolant valve of changed, a transfer path of the coolant flowing in the plurality of cooling flow paths may be changed.

The control unit may determine whether a mode change of the coolant valve is needed, and when it is determined that a mode change of the coolant valve is needed, the control unit may check an operational command speed of the coolant pump.

When the operational command speed of the coolant pump exceeds the preset RPM, the control unit may control the coolant pump to operate at the preset RPM.

When the operational command speed of the coolant pump is 0, the control unit may control the coolant pump to maintain a stopped state.

When the operational command speed of the coolant pump is the preset RPM, the control unit may control the coolant pump to maintain the preset RPM.

When a mode change of the coolant valve is completed, the control unit may return an operational speed of the coolant pump to the operational command speed.

Another embodiment is a method for controlling a coolant module system, including:

determining whether a mode change of a coolant valve is needed; checking an operational speed of a coolant pump; controlling the operational speed of the coolant pump to be equal to or below a preset RPM (revolutions per minute) when the mode change of the coolant valve is needed; and changing a mode of the coolant valve.

In the method for controlling a coolant module system, the changing a mode of the coolant valve may include: changing a transfer path of a coolant flowing in a plurality of cooling flow paths connected to the coolant valve.

In the method for controlling a coolant module system, the checking an operational speed of a coolant pump may include: checking an operational command speed of the coolant pump.

In the method for controlling a coolant module system, the controlling the operational speed of the coolant pump may include: controlling the coolant pump to operate at the preset RPM when the operational command speed of the coolant pump exceeds the preset RPM.

In the method for controlling a coolant module system, the controlling the operational speed of the coolant pump may include: controlling the coolant pump to maintain a stopped state when the operational command speed of the coolant pump is 0.

In the method for controlling a coolant module system, the controlling the operational speed of the coolant pump may include: controlling the coolant pump to maintain the preset RPM when the operational command speed of the coolant pump is the preset RPM.

The method may include: determining whether a mode change of the coolant valve is completed; and returning an operational speed of the coolant pump to the operational command speed when it is determined that the mode change of the coolant valve is completed.

Other details of the embodiments are included in the detailed description and the accompanying drawings.

According to the embodiments, it is possible to provide a coolant module system capable of reducing noise and/or vibration when changing a flow path in a state in which the flow rate of the coolant is great, and a method for controlling the coolant module system.

The advantageous effects of the present disclosure are not limited to the effects described above, and more diverse effects are included in the present disclosure.

### DESCRIPTION OF DRAWINGS

FIG. 1 is a block diagram of a coolant module system according to an embodiment.

FIGS. 2A to 2D are diagrams illustrating a mode change of a coolant valve according to an embodiment.

FIG. 3 is a flowchart of a method for controlling a coolant module system according to an embodiment.

### DESCRIPTION OF EMBODIMENTS

Advantages and characteristics of the present disclosure and a method of achieving the advantages and characteristics will be clear by referring to exemplary embodiments described below in detail together with the accompanying drawings. However, the present disclosure is not limited to exemplary embodiment disclosed herein but will be implemented in various forms. The exemplary embodiments are provided by way of example only so that a person of ordinary skilled in the art can fully understand the disclosures of the present disclosure and the scope of the present disclosure. Therefore, the present disclosure will be defined only by the scope of the appended claims.

Although the terms “first”, “second”, and the like are used for describing various

components, these components are not confined by these terms. These terms are merely used for distinguishing one component from the other components. Therefore, a first component to be mentioned below may be a second component in a technical concept of the present disclosure.

Hereinafter, various exemplary embodiments of the present disclosure will be described in detail with reference to accompanying drawings.

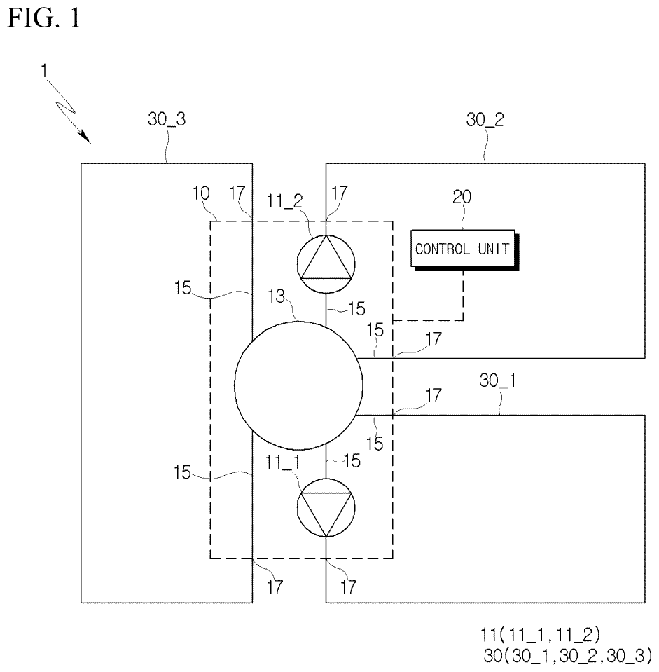

FIG. 1 is a block diagram of a coolant module system according to an embodiment.

A coolant module system 1 for an electric vehicle may include a coolant module 10 and a control unit 20.

The coolant module 10 may configure a coolant circuit of an electric cooling system of a vehicle and may control a flow rate and a direction of a flow path of a coolant. In the embodiment, the coolant module 10 has integrated each component, such as a coolant pump 11 and a coolant valve 13, which has been mounted separately on the conventional cooling system and configures the cooling circuit by being connected to one another through hoses etc. into one module. Therefore, the coolant module 10 may control not only a flow rate of the coolant, but also, a direction of the flow path of the coolant.

The coolant module 10 may include at least one coolant pump 11 configured to pressurize the coolant and to transfer the coolant, and a coolant valve 13 configured to control a flow of the coolant in a plurality of directions.

The coolant pump 11 may be an electric water pump (EWP). In one embodiment, two coolant pumps 11_1 and 11_2 connected to each different flow path may be provided in the coolant module 10, but the embodiment is not limited thereto. A quantity and arrangement of the coolant pump 11 may vary greatly according to a design of the coolant circuit.

The coolant valve 13 may be a multi-direction changeover valve. As a direction of the multi-direction changeover valve is changed and a flow of the coolant is changed accordingly, a transfer path of the coolant may be changed. In some embodiments, the coolant valve 13 may be a coolant branch valve configured to branch a transfer direction of the coolant, and the coolant branch valve may be a multi-direction valve.

The coolant module 10 may further include a plurality of internal flow paths 15, and a plurality of coolant inlets/outlets 17 formed therein.

The internal flow path 15 may connect components forming the coolant module 10 to one another. In the embodiment, the internal flow path 15 may connect the coolant pump 11 and the coolant valve 13. The internal flow path 15 may be communicated with the plurality of coolant inlets/outlets 17 of the coolant module 10. The plurality of coolant inlets/outlets 17 may allow the coolant to be discharged outside, or to be introduced into the inside. Here, the outside means the cooling circuit of the electric cooling system, and other component in the electric cooling system of a vehicle, for example, a PE part, a battery, a chiller, and the like. That is, it is possible to connect different components of the cooling circuit to one another through the coolant inlet/outlet 17 such that the coolant can flow between the different components of the cooling circuit.

At one point in the coolant module 10, that is, at one point in the internal flow path 15, a flow path changeover part in which the coolant valve 13 is provided may be formed. The internal flow path 15 may be formed such that the internal flow path 15 branches off in a plurality of directions on the basis of the flow path changeover part. In some embodiments, the internal flow path 15 branched off in any one direction may branch off again at an intermediate point of the corresponding internal flow path 15.

In the embodiment, a 6-way changeover valve may be mounted such that the internal flow path 15 inside the coolant module 10 branches off in six directions. However, the embodiment is not limited thereto, and a quantity of the plurality of internal flow paths 15 and a kind of the coolant valve 13 may be selected suitably considering the whole circuit configuration of the cooling circuit. For example, a quantity of the plurality of internal flow paths 15 may be three, four, or five, etc. and therefore, a 3-way, a 4-way, or a 5-way changeover valve may be used as the coolant valve 13. Meanwhile, the changeover valve may be operated in operational methods such as manual, mechanical, hydraulic/pneumatic, electronic, and electro-hydraulic/pneumatic operation methods.

The coolant module system 1 may include a plurality of cooling flow paths 30. The plurality of cooling flow paths 30 may form the cooling circuit of the electric cooling system of a vehicle. The internal flow path 15 may form a part of a cooling flow path 30.

In the embodiment, the plurality of cooling flow paths 30 may include first to third cooling flow paths 30_1, 30_2 and 30_3 configured to be connected to the coolant valve 13. A first coolant pump 11_1 may be disposed in the first cooling flow path 30_1, and a second coolant pump 11_2 may be disposed in the second cooling flow path 30_2. However, the embodiment is not limited thereto, and a quantity and arrangement of the cooling flow path 30 may vary greatly according to a design of the coolant circuit.

As above-described, the coolant valve 13 may be a multi-direction changeover valve. In the multi-direction changeover valve, input/output ports may be provided in at least two or more directions on the basis of the valve. It is possible to change a transfer direction of the coolant by changing a port to/from which the coolant is input/output through a changeover of a direction of the valve. In some embodiment, the coolant module 10 may further include a drive motor configured to drive the coolant valve 13.

In the embodiment, the coolant valve 13 may be driven in a plurality of modes, each of which corresponds to a plurality of valve directions. The mode control of the coolant valve 13 may be performed by a control unit 20 which will be described below, or by other control unit which is provided separately from the control unit 20 in the vehicle.

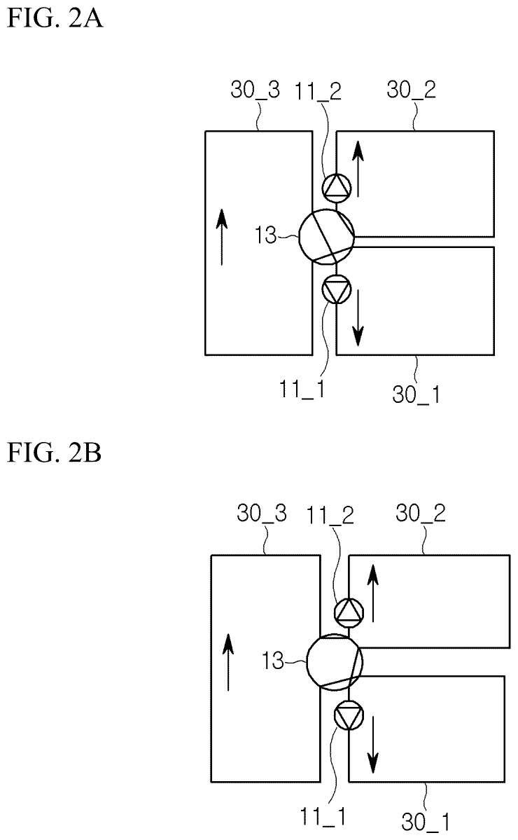

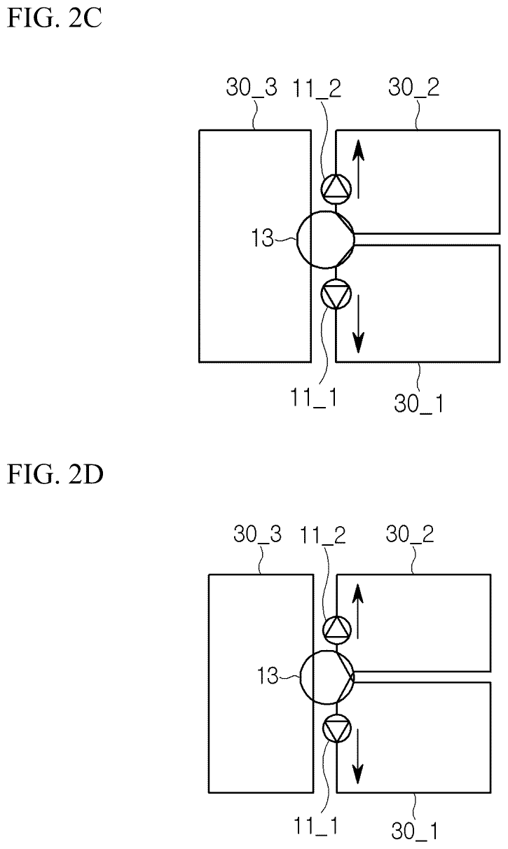

Referring to FIGS. 2A to 2D, a mode change of the coolant valve 13 will be described.

FIGS. 2A to 2D are diagrams illustrating a mode change of the coolant valve according to the embodiment.

FIG. 2A is a diagram illustrating a case in which the coolant valve 13 is in a first mode. FIG. 2B is a diagram illustrating a case in which the coolant valve 13 is in a second mode. FIG. 2C is a diagram illustrating a case in which the coolant valve 13 is in a third mode. FIG. 2D is a diagram illustrating a case in which the coolant valve 13 is in a fourth mode.

Referring to FIGS. 2A to 2D, in the coolant module system 1, each mode of the coolant valve 13 may provide at least one coolant transfer path which is different from transfer paths of other modes. The coolant valve 13 may be driven to change over to two or more modes providing each different coolant transfer path. For example, the coolant valve 13 may be driven in at least two or more modes among the first to fourth modes illustrated in FIGS. 2A to 2D. Referring to FIG. 2A, in the first mode, the coolant valve 13 may be driven to connect the first and the third cooling flow paths 30_1 and 30_3 to form one circulation loop, and to allow the second cooling flow path 30_2 to form one circulation loop isolated from the other cooling flow paths 30_1 and 30 3.

Referring to FIG. 2B, in the second mode, the coolant valve 13 may be driven to connect the first to the third cooling flow paths 30_1, 30_2, and 30_3 so that the first to the third cooling flow paths 30_1, 30_2, and 30_3 form one circulation loop.

Referring to FIG. 2C, in the third mode, the coolant valve 13 may be driven such that each of the first to the third cooling flow paths 30_1, 30_2, and 30_3 forms a separate circulation loop.

Referring to FIG. 2D, in the fourth mode, the coolant valve 13 may be driven such that first and the second cooling flow paths 30_1 and 30_2 form one circulation loop, and the cooling flow path 30_3 forms one circulation loop.

The transfer direction of the coolant in each of the cooling flow path 30 may be determined according to a pressure transfer direction of the coolant pump 11. The transfer direction of the coolant is illustrated in a solid arrow in FIGS. 2A to 2D. As illustrated in FIGS. 2A to 2D, even if the mode of the coolant valve 13 is changed, the transfer direction of the coolant in each of the cooling flow paths 30 may be the same.

When the mode of the coolant valve 13 is changed, the transfer path of the coolant may be changed. The change of the transfer path of the coolant may be achieved by a change of connection relationships between the plurality of cooling flow paths 30 according to a redirection of the coolant valve 13. The connection relationships between the plurality of cooling flow paths 30 may be designed suitably considering the cooling circuit of the cooling system.

When the mode of the coolant valve 13 is changed, any one among the plurality of cooling flow paths 30 may be connected to a different cooling flow path 30 from the cooling flow path 30 connected before, or may be isolated from other cooling flow paths 30 forming the plurality of cooling flow paths 30.

A coolant transfer path provided by any one mode may be different from that of other modes. A coolant transfer path provided by any one mode may be the same as or different from that of other modes. When a coolant transfer path provided by any one mode is the same as that of other modes, the connection relationships between the plurality of cooling flow paths 30 forming the coolant transfer path may be different. For example, as illustrated in FIGS. 2A to 2B, two coolant transfer paths may be provided in the first mode, one coolant transfer path may be provided in the second mode, three coolant transfer paths may be provided in the third mode, two coolant transfer paths may be provided in the fourth mode, and the coolant transfer path may vary with respect to each of the modes.

When the mode of the coolant valve 13 is changed, a case of which a transfer path of the coolant is dramatically or sharply changed may occur.

For example, referring to FIGS. 2A and 2B, when changeover from the first mode to the second mode is performed, the coolant flowing in the second coolant flow path 30_2 may be introduced into the first coolant flow path 30_1 suddenly. In addition, the coolant flowing in the third coolant flow path 30_3 may be introduced into the second coolant flow path 30_2 suddenly.

For another example, referring to FIGS. 2B and 2C, when changeover from the third mode to the second mode is performed, the coolant flowing in the second coolant flow path 30_2 may be introduced into the first coolant flow path 30_1 suddenly. In addition, the coolant flowing in the first coolant flow path 30_1 may be introduced into the third coolant flow path 30_3 suddenly.

For another example, referring to FIGS. 2C and 2D, when changeover from the third mode to the fourth mode is performed, the coolant flowing in the first coolant flow path 30_1 may be introduced into the second coolant flow path 30_2 suddenly, and the coolant flowing in the second coolant flow path 30_2 may be introduced into the first coolant flow path 30_1 suddenly.

For another example, referring to FIGS. 2D and 2A, when changeover from the fourth mode to the first mode is performed, the coolant flowing in the first coolant flow path 30_1 may be introduced into the third coolant flow path 30_3 suddenly.

In cases of the mode combinations other than those mentioned above and the changeovers between them, it is apparent that there may occur a case in which the transfer path of the coolant is dramatically or sharply changed. In addition, a case, in which the transfer path of the coolant is dramatically or sharply changed, may include not only a case in which the coolant is introduced into other cooling flow paths 30 suddenly, but also, a case in which one among the plurality of cooling flow paths 30 is isolated from other cooling flow paths 30 suddenly.

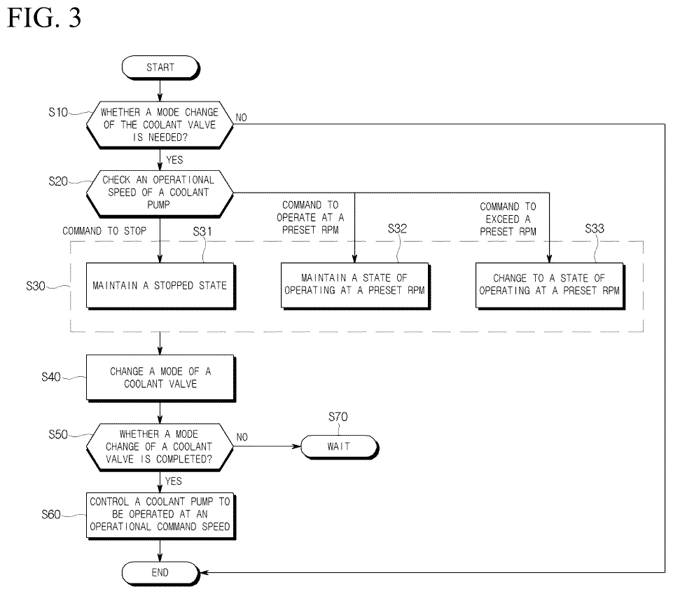

As described above, when the transfer path of the coolant is dramatically or sharply changed, there may occur noise and/or vibration due to instability of the flow path. An operation in detail of the control unit 30 for preventing the noise and/or vibration will be described below referring to FIG. 3.

Referring to FIG. 1 again, the control unit 20 may control an operation of the coolant pump 11 and the coolant valve 13. The control unit 20 may include a processor. The control unit 20 may further include a memory for storing data. In FIG. 1, the control unit 20 is illustrated separately from the coolant module 10, but is not limited thereto. In some embodiment, the control unit 20 may be included in the coolant module 10 and/or the coolant pump 11. In some embodiment, the control unit 20 may further control other component of the coolant module 10. In some embodiment, the control unit 20 may control overall operations of the electric vehicle, and may include controlling the coolant pump 1 as a part of the functions of the overall operations of the electric vehicle.

FIG. 3 is a flowchart of a method for controlling the coolant module system according to the embodiment.

A method for controlling the coolant module system which will be described below may be performed by the coolant module system 1.

Referring to FIG. 3, the method for controlling the coolant module system according to the embodiment may include determining whether a mode change of the coolant valve 13 is needed (S10); checking an operational speed of the coolant pump 11 (S20); controlling the operational speed of the coolant pump 11 to be equal to or below a preset RPM (revolutions per minute) when a mode change of the coolant valve 13 is needed (S30); and changing a mode of the coolant valve 13 (S40).

In the operation S10, the control unit 20 may determine whether a mode change of the coolant valve 13 is needed. For example, the control unit 20 may determine whether it is needed to change the mode of the coolant valve 13 from one among the first to the fourth modes to another one.

In the operation S20, when it is determined that the change of the mode of the coolant

valve 13 is needed, the control unit 20 may check an operational speed of the coolant pump 11. In the embodiment, the control unit 20 may check an operational command speed of the coolant pump 11. The control unit 20 may detect the operational speed of the coolant pump 11 based on the operational command speed of the coolant pump 11. The operational command speed may be a speed value or a speed range included in an operational command signal provided to the coolant pump 11 in advance and instructing the operation of the coolant pump 11. The coolant pump 11 may be operated according to the speed instructed by the operational command before the control unit 20 controls the operational speed of the coolant pump 11 according to an operation S30. In some embodiment, the operational speed of the coolant pump may be detected by a separate sensor provided in the coolant module 10. In some embodiment, the control unit 20 may further determine whether the transfer direction of the coolant of at least one cooling flow path 30 is changed when a mode of the coolant valve 13 is changed, and may perform control of the operational speed of the coolant pump 11 based on the determination.

In the operation S30, the control unit 20 may control the operational speed of the coolant pump 11 to be equal to or less than the preset RPM based on the checked operational speed of the coolant pump 11. The preset RPM may be the minimum RPM for maintaining the coolant valve 13 in the operational state.

As described above, the coolant module system 1 may be configured such that the transfer path of the coolant flowing in the plurality of cooling flow paths 30 is changed when the mode of the coolant valve 13 is changed. In this case, in particular, in a state in which the coolant pump 11 rotates at a high speed and the flow rate of the coolant is great, unnecessary noise and/or vibration may occur. In order to solve such a problem, the operational speed of the coolant pump 11 may be controlled to be equal to or less than the preset minimum RPM when the mode change of the coolant valve 13 is performed.

In the operation S30, according to the checked operational speed of the coolant pump 11, the control unit 20 may change the operational speed of the coolant pump 11 to the preset RPM, or maintain the checked operational speed of the coolant pump 11.

The operation S30 may include an operation S31 in which the control unit 20 controls the coolant pump 11 such that the coolant pump 11 maintains a stopped state when the operational command speed of the coolant pump 11 is 0.

The operation S30 may include an operation S32 in which the control unit 20 controls the coolant pump 11 such that the coolant pump 11 maintains the preset RPM when the operational command speed of the coolant pump 11 is the preset RPM.

The operation S30 may include an operation S33 in which the control unit 20 controls the coolant pump 11 such that the coolant pump 11 operates at the preset RPM when the operational command speed of the coolant pump 11 exceeds the preset RPM.

In the operation S33, when the operational command speed of the coolant pump 11 exceeds the preset RPM, the control unit 20 may ignore the operational command instructed to the coolant pump 11 in advance, and operate the coolant pump 11 at the preset RPM. That is, in the operation S33, the control unit 20 may operate the coolant pump 11 at the preset RPM, instead of the operational command speed.

After the operation S30 is completed, the method for controlling the coolant module system may perform an operation S40 for changing the mode of the coolant valve 13. As described above, as the mode of the coolant valve 13 is changed, the transfer path of the coolant flowing in the plurality of cooling flow paths 30 may be changed. In some embodiment, the coolant valve 13 may be controlled by a separate control unit which is different from the control unit 20, and in such a case, the operation S40 may be omitted.

The method for controlling the coolant module system may further include an operation S50 for determining whether a mode change of the coolant valve 13 is completed, and an operation S60 for returning an operational speed of the coolant pump 11 to the operational command speed when it is determined that the mode change of the coolant valve 13 is completed.

In the operation S50, the control unit 20 may determine whether the mode change of the coolant pump 13 is completed based on a received mode changeover completion signal. The mode changeover completion signal may be received from the coolant valve 13 or a separate control unit configured to control the coolant valve 13.

In the operation S60, when it is determined that the mode change of the coolant pump 13 is completed, the control unit 20 may control the coolant pump 11 such that the coolant pump 11 is operated at the operational speed before the operational speed change by the operation S30. In the embodiment, when it is determined that the mode change of the coolant pump 13 is completed, the control unit 20 may control the coolant pump 11 such that the coolant pump 11 is operated again at the checked operational command speed which has been checked in the operation S20.

The method for controlling the coolant module system may further include an operation S70 for waiting until the mode change of the coolant pump 13 is completed when it is determined that the mode change of the coolant pump 13 is not completed.

As described above, by controlling the operational speed of the cooling pump 11 to be the minimum RPM at the time of the mode change of the coolant valve 13, the method for controlling the coolant module system may reduce noise and/or vibration caused by a change of the transfer flow path, and may provide an improved cooling performance because the operation of the coolant pump 11 need not be stopped for every mode change.

The embodiments of the present disclosure have been described with reference to accompanying drawings. Those of ordinary skill in the art will recognize that the present invention may be embodied in other specific forms without departing from its spirit or essential characteristics. The described embodiments are to be considered in all respects only as illustrative and not restrictive.

What is claimed is:

1. A coolant module system, comprising:
a coolant pump configured to press and transfer a coolant;
a coolant valve configured to control a flow of the coolant in a plurality of directions; and
a control unit configured to control operations of the coolant pump and the coolant valve and to control an operational speed of the coolant pump to be equal to or below a preset RPM (revolutions per minute) when a mode of the coolant valve is changed.

2. The coolant module system of claim 1, further comprising:
a plurality of cooling flow paths connected to the coolant valve, wherein when the mode of the coolant valve is changed, a transfer path of the coolant flowing in the plurality of cooling flow paths is changed.

3. The coolant module system of claim 1, wherein the control unit determines whether a mode change of the coolant valve is needed, and when it is determined that the mode change of the coolant valve is needed, the control unit checks an operational command speed of the coolant pump.

4. The coolant module system of claim 3, wherein when the operational command speed of the coolant pump exceeds the preset RPM, the control unit controls the coolant pump to operate at the preset RPM.

5. The coolant module system of claim 3, wherein when the operational command speed of the coolant pump is 0, the control unit controls the coolant pump to maintain a stopped state.

6. The coolant module system of claim 3, wherein when the operational command speed of the coolant pump is at the preset RPM, the control unit controls the coolant pump to maintain the preset RPM.

7. The coolant module system of claim 4, wherein when the mode change of the coolant valve is completed, the control unit returns the operational speed of the coolant pump to the operational command speed.

8. A method for controlling a coolant module system, the method comprising:
determining whether a mode change of a coolant valve is needed;
checking an operational speed of a coolant pump;
controlling the operational speed of the coolant pump to be equal to or below a preset RPM (revolutions per minute) when the mode change of the coolant valve is needed; and
changing a mode of the coolant valve.

9. The method of claim 8, wherein the changing the mode of the coolant valve further comprises:
changing a transfer path of a coolant flowing in a plurality of cooling flow paths connected to the coolant valve.

10. The method of claim 8, wherein the checking the operational speed of the coolant pump further comprises:
checking an operational command speed of the coolant pump.

11. The method of claim 10, wherein the controlling the operational speed of the coolant pump further comprises:
controlling the coolant pump to operate at the preset RPM when the operational command speed of the coolant pump exceeds the preset RPM.

12. The method of claim 10, wherein the controlling the operational speed of the coolant pump further comprises:
controlling the coolant pump to maintain a stopped state when the operational command speed of the coolant pump is 0.

13. The method of claim 10, wherein the controlling the operational speed of the coolant pump further comprises:
controlling the coolant pump to maintain the preset RPM when the operational command speed of the coolant pump is at the preset RPM.

14. The method of claim 11, further comprising:
determining whether the mode change of the coolant valve is completed; and
returning the operational speed of the coolant pump to the operational command speed when it is determined that the mode change of the coolant valve is completed.
